(19) United States
(12) Patent Application Publication
(10) Pub. No.: US 2008/0054387 A1
(43) Pub. Date: Mar. 6, 2008

(54) Image Sensor and Method for Manufacturing the Same

(76) Inventor: YUNG PIL KIM, ECHEON-SI (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/780,020

(22) Filed: Jul. 19, 2007

(30) Foreign Application Priority Data
Aug. 31, 2006 (KR) 10-2006-0083909

(51) Int. Cl. H01L 31/0232; H01L 31/18

(52) U.S. Cl. 257/432; 438/70; 257/E31.127

(57) ABSTRACT

An image sensor is provided. The image sensor includes a first passivation layer, a color filter layer, microlenses, an uppermost conducting layer, a second passivation layer, and a third passivation layer. The first passivation layer is formed on a substrate including a predetermined pixel portion and a logic pad portion. The color filter layer and the microlenses are formed on a portion of the first passivation layer corresponding to the pixel portion. The uppermost conducting layer is formed in a portion of the first passivation layer that corresponds to the logic pad portion. The second passivation layer is formed on the first passivation layer corresponding to the logic pad portion to expose a portion of the uppermost conducting layer. The third passivation layer is formed on the second passivation layer to expose the uppermost conducting layer.

### CROSS-REFERENCE TO RELATED APPLICATION

The present application claims the benefit under 35 U.S.C. §119 of Korean Patent Application No. 10-2006-0083909, filed Aug. 31, 2006, which is hereby incorporated by reference in its entirety.

### BACKGROUND

Generally, an image sensor is a semiconductor device that converts optical images into electrical signals. Image sensors are roughly divided into charge coupled devices (CCDs) and complementary metal oxide semiconductor (CMOS) image sensors (CISs).

The CISs include a photodiode and a MOS transistor in a unit pixel and sequentially detect electrical signals from respective unit pixels in a switching manner to realize an image.

According to a related art, since the thickness of a passivation layer including a first insulating layer and a second insulating layer on an uppermost conducting layer of a CIS is very thick, a distance from a condensing portion including a color filter layer and microlenses to a photodiode, which is a light detecting portion, is very long, so that an image characteristic deteriorates.

### BRIEF SUMMARY

Embodiments provide an image sensor and a method for manufacturing the same, that can improve an image characteristic of a CMOS image sensor by reducing a distance between a condensing portion and a sensor portion.

In one embodiment, an image sensor includes: a first passivation layer on a substrate including a predetermined pixel portion and a logic pad portion; a color filter layer and microlenses formed on a portion of the first passivation layer that corresponds to the pixel portion; an uppermost conducting layer in a portion of the first passivation layer that corresponds to the logic pad portion; a second passivation layer on the first passivation layer corresponding to the logic pad portion to expose a portion of the uppermost conducting layer; and a third passivation layer on the second passivation layer to expose the uppermost conducting layer.

In another embodiment, a method for manufacturing an image sensor includes: forming a first passivation layer on a substrate including a predetermined pixel portion and a predetermined logic pad portion; forming an uppermost conducting layer in a portion of the first passivation layer that corresponds to the logic pad portion; sequentially forming a second passivation layer and a third passivation layer on an entire surface of the first passivation layer including the uppermost conducting layer; exposing portions of the first passivation layer and the uppermost conducting layer that correspond to the pixel portion; and sequentially forming a color filter layer and microlenses on the exposed portion of the first passivation layer that corresponds to the pixel portion.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view of a CMOS image sensor according to an embodiment.

FIGS. 2 to 5 are cross-sectional views for explaining a method for manufacturing a CMOS image sensor according to an embodiment.

### DETAILED DESCRIPTION

Reference will now be made in detail to embodiments of the present disclosure, examples of which are illustrated in the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, and one or more intervening layers may also be present. In addition, it will also be understood that when a layer is referred to as being ‘between’ two layers, it can be the only layer between the two layers, or one or more intervening layers may also be present.

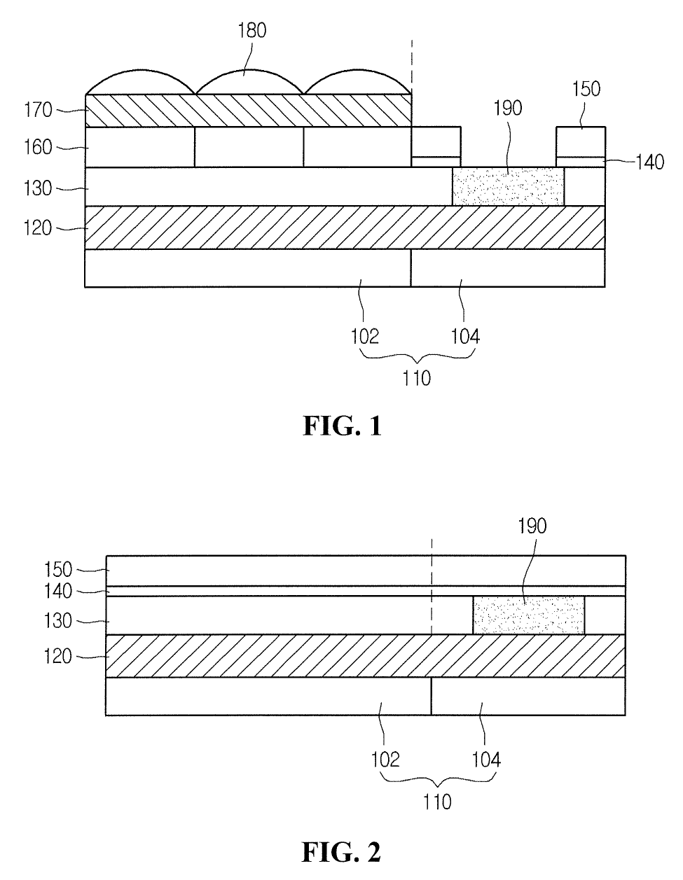

FIG. 1 is a cross-sectional view of a CMOS image sensor according to an embodiment.

The CMOS image sensor is divided into a pixel portion 102 and a logic pad portion 104. The CMOS image sensor can include: a substrate 110 on which a first passivation layer 130 is formed; a color filter layer 160 and microlenses 180 sequentially formed on a portion of the first passivation layer 130 that corresponds to the pixel portion 102; an uppermost conducting layer 190 formed in a portion of the first passivation layer 130 that corresponds to the logic pad portion 104; a second passivation layer 140 formed on a portion of the first passivation layer 130 corresponding to the logic pad portion 104 to expose a portion of the uppermost conducting layer 190; and a third passivation layer 150 formed on the second passivation layer 140 to expose the uppermost conducting layer 190.

A further embodiment can include an insulating layer 120 formed between the substrate 110 and the first passivation layer 130.

Also, an embodiment can further include a planarization layer 170 between the color filter layer 160 and the microlenses 180.

In a CMOS image sensor according to an embodiment, the condensing portion including the color filter layer can be located a closer distance to the substrate than a related art.

In one embodiment, the condensing portion can be closer by a distance equal to the sum of the thicknesses of the second passivation layer and the third passivation layer. Accordingly, a distance to a sensor portion can be reduced, and an image characteristic can be considerably improved.

FIGS. 2 to 5 are cross-sectional views for explaining a method for manufacturing a CMOS image sensor according to an embodiment.

A manufacturing process of the CMOS image sensor will be descried according to an embodiment.

First, referring to FIG. 2, a substrate 110 having a predetermined pixel portion 102 and logic pad portion 104, and including a first passivation layer 130 can be prepared. An uppermost conducting layer 190 can be formed in the first passivation layer 130 of the logic pad portion. After that, a second passivation layer 140 and a third passivation layer 150 can be sequentially formed on the entire surface of the first passivation layer 130 including the uppermost conducting layer 190.

That is, after a semiconductor basic device and wiring process is performed, the first passivation layer 130 is stacked on the semiconductor substrate 110 that can be insulated by an insulating layer 120. The uppermost conducting layer 190 can be deposited on the first passivation layer 130 such that the conducting layer fills patterns in the first passivation layer 130 of the logic pad portion 104, and then the resulting layer is planarized using chemical mechanical polishing (CMP). The second passivation layer 140 and the third passivation layer 150 are then formed on the planarized layer.

The second passivation layer 140 can be selected to have a higher selectivity than the first and third passivation layers 130 and 150.

For example, the second passivation layer 140 can be a silicon nitride layer, and the first and third passivation layers 130 and 150 can be oxide layers.

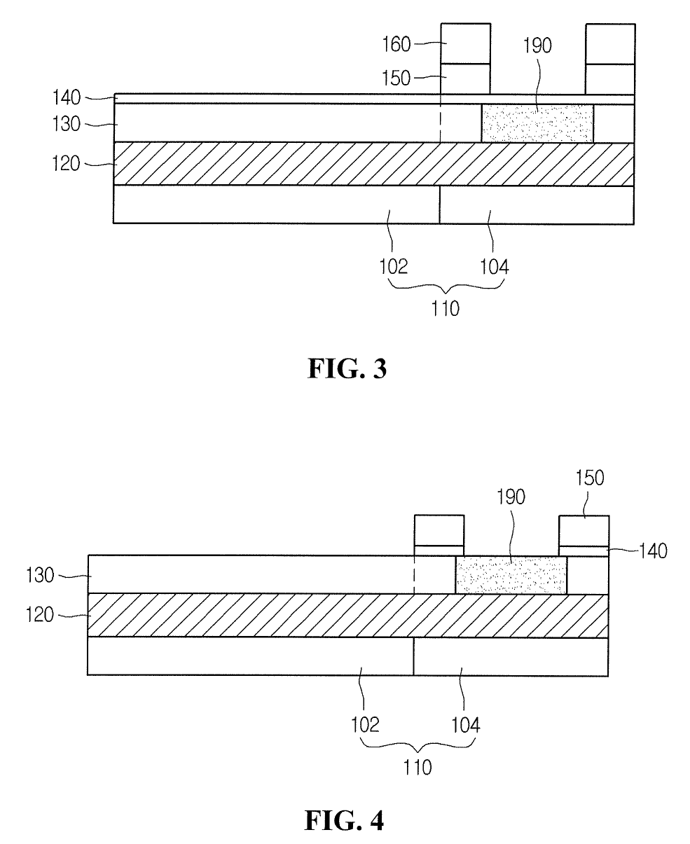

Next, referring to FIG. 3, a portion of the third passivation layer 150 corresponding to the pixel portion 102 is entirely etched, and a portion of the third passivation layer 150 corresponding to the uppermost conducting layer 190 on the logic pad portion is selectively etched to expose the second passivation layer 140 on the pixel portion and a portion of the second passivation layer 140 on the uppermost conducting layer.

That is, in one embodiment, resist is coated on the structure of FIG. 2 to form photoresist layer patterns 160 as shown in FIG. 3. A portion of the third passivation layer 150 where a bonding pad is to be formed is removed through an etching process using the photoresist layer patterns 160 as an etch mask. At this point, not only a bonding pad region but also a pixel array can be simultaneously opened to remove a portion of the third passivation layer 150 corresponding to a pixel array.

The etching selectivity of the third passivation layer 150 to the second passivation layer 140 can be high. For example, the etching selectivity can be about 10:1 or more.

Next, a portion of the second passivation layer 140 that corresponds to the pixel portion is entirely etched, and a portion of the second passivation layer 140 on the uppermost conducting layer 190 is selectively etched to expose the first passivation layer 130 of the pixel portion 102 and the uppermost conducting layer 190.

That is, in one embodiment, after the photoresist layer patterns 160 are removed, the second passivation layer 140 is etched using the remaining third passivation layer 150 as a mask. The photoresist layer patterns 160 can be removed and the second passivation layer 140 can be etched using the etched third passivation layer 150 as an etch mask when the etching selectivity of the third passivation layer 150 to the second passivation layer 140 is, for example, about 10:1 or more. At this point, uniform etching can be performed.

Meanwhile, in another embodiment, the photoresist layer patterns 160 are not removed, but used as an etch mask in etching the exposed second passivation layer 140 to expose a portion of the first passivation layer 130 that corresponds to the pixel portion, and the uppermost conducting layer 190.

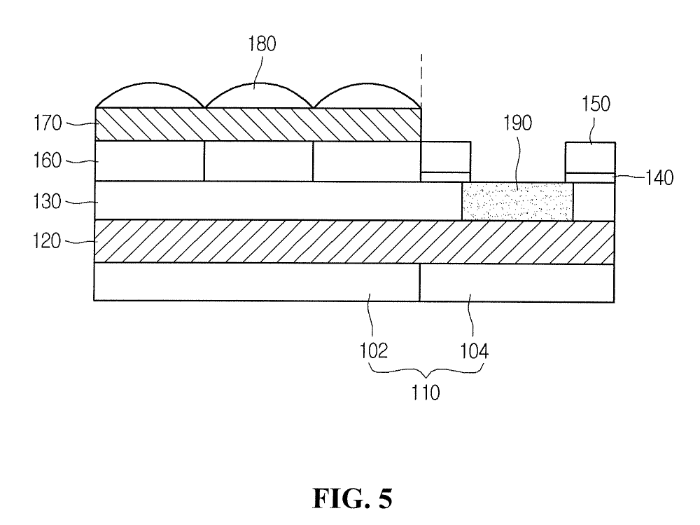

Next, referring to FIG. 5, a color filter layer 160 and microlenses 180 can be sequentially formed on the exposed portion of the first passivation layer 130 that corresponds to the pixel portion.

Also, according to an embodiment, a planarization layer 170 can be further formed between the color filter layer 160 and the microlenses 180.

In an image sensor and a method for manufacturing the same according to an embodiment, since a condensing portion including the color filter layer is located lower by the sum of the thicknesses of the second passivation layer and the third passivation layer compared to a related art, a distance to a sensor portion reduces, and an image characteristic considerably improves.

Also, according to an embodiment, since only a process of stacking the second passivation layer is added and a process of opening the bonding pad region is directly used, an additional process is not required, and reduction in yield is not generated.

Also, according to an embodiment, when the pixel array is etched, over-etching of the pixel array can be prevented by the second passivation layer having high etching selectivity, so that the thickness of the insulating layer remaining on the pixel array is uniform and uniformity within a chip of an image characteristic can be improved.

Also, according to an embodiment, an amount of etching can be controlled on the whole. Since the amount of etching is not much, color filters and microlens patterns can be easily formed, and a defect that these elements fall down can be prevented.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a first passivation layer on a substrate, the first passivation layer comprising a pixel portion and a logic pad portion;
a color filter layer formed on a portion of the first passivation layer corresponding to the pixel portion;
microlenses formed on the color filter layer on the pixel portion;
an uppermost conducting layer formed in a portion of the first passivation layer that corresponds to the logic pad portion;
a second passivation layer on the first passivation layer corresponding to the logic pad portion, and formed to expose a portion of the uppermost conducting layer; and
a third passivation layer on the second passivation layer on the logic pad portion, and formed to expose the uppermost conducting layer.

2. The image sensor according to claim 1, further comprising an insulating layer between the substrate and the first passivation layer.

3. The image sensor according to claim 1, further comprising a planarization layer between the color filter layer and the microlenses.

4. The image sensor according to claim 1, wherein the second passivation layer has a higher etching selectivity than the first and second passivation layers.

5. The image sensor according to claim 4, wherein etching selectivity of the third passivation layer to the second passivation layer is at least 10:1.

6. The image sensor according to claim 1, wherein the second passivation layer comprises a silicon nitride layer, the first passivation layer comprises an oxide layer, and the third passivation layer comprises an oxide layer.

7. A method for manufacturing an image sensor, the method comprising:
forming a first passivation layer on a substrate, the first passivation layer comprising a predetermined pixel portion and a predetermined logic pad portion;
forming an uppermost conducting layer in a portion of the first passivation layer that corresponds to the logic pad portion;
sequentially forming a second passivation layer and a third passivation layer on an entire surface of the first passivation layer including the uppermost conducting layer;
exposing a portion of the first passivation layer that corresponds to the pixel portion and the uppermost conducting layer;
forming a color filter layer on the exposed portion of the first passivation layer that corresponds to the pixel portion; and
forming microlenses on the color filter layer on the pixel portion.

8. The method according to claim 7, wherein exposing the portion of the first passivation layer that corresponds to the pixel portion and the uppermost conducting layer comprises:
etching the third passivation layer to expose a portion of the second passivation layer that corresponds to the pixel portion and a portion of the second passivation layer that corresponds to the uppermost conducting layer; and
etching the second passivation layer to expose the portion of the first passivation layer that corresponds to the pixel portion and the uppermost conducting layer.

9. The method according to claim 8, wherein etching the third passivation layer comprises:
forming photoresist patterns on the third passivation layer that entirely expose a portion of the third passivation layer that corresponds to the pixel portion and selectively expose a portion of the third passivation layer that corresponds to the uppermost conducting layer on the logic pad portion; and
etching the exposed portions of the third passivation layer using the photoresist patterns as an etch mask to expose a portion of the second passivation layer that corresponds to the pixel portion and a portion of the second passivation layer that corresponds to the uppermost conducting layer.

10. The method according to claim 9, wherein etching the second passivation layer comprises:
etching the exposed portions of the second passivation layer using the photoresist patterns as an etch mask.

11. The method according to claim 9, wherein etching the second passivation layer comprises:
removing the photoresist patterns: and
etching the exposed portions of the second passivation layer using the etched third passivation layer as an etch mask.

12. The method according to claim 7, further comprising forming a planarization layer between the color filter layer and the microlenses.

13. The method according to claim 7, further comprising, after forming the first passivation layer, planarizing the first passivation layer.

14. The method according to claim 7, wherein the second passivation layer has a higher etching selectivity than the first and second passivation layers.

15. The method according to claim 14, wherein etching selectivity of the third passivation layer to the second passivation layer is at least 10:1.

16. The method according to claim 7, wherein the second passivation layer comprises a silicon nitride layer, the first passivation layer comprises an oxide layer, and the third passivation layer comprises an oxide layer.
